(19) United States
(12) Patent Application Publication
(10) Pub. No.: US 2016/0268323 A1
(43) Pub. Date: Sep. 15, 2016

(54) SOLID-STATE IMAGING DEVICE AND METHOD FOR MANUFACTURING THE SAME

(71) Applicant: Kabushiki Kaisha Toshiba, Tokyo (JP)

(72) Inventor: Yasuhisa Oomuro, Komatsu Ishikawa (JP)

(21) Appl. No.: 14/845,193

(22) Filed: Sep. 3, 2015

(30) Foreign Application Priority Data
Mar. 12, 2015 (JP) 2015-049046

(51) Int. Cl. H01L 27/146

(52) U.S. Cl. CPC H01L 27/14605; H01L 27/14629; H01L 27/14627; H01L 27/1463; H01L 27/14685

(57) ABSTRACT

According to one embodiment, a solid-state imaging device includes substrate; first color light separation section; first layer; first light collecting section; second color light separation section; second layer; second light collecting section. The substrate includes first region receiving first color light, second region receiving the first color light, third light receiving region receiving a second color light, and fourth region receiving third color light. The first color light separation section has first inclined surface. The first layer is provided on the first color light separation section. The first light collecting section is provided above the first region. The second color light separation section has second inclined surface. The second layer is provided on the second color light separation section. The second light collecting section is provided above the second region.

### CROSS-REFERENCE TO RELATED APPLICATIONS

This application is based upon and claims the benefit of priority from Japanese Patent Application No. 2015-049046, filed on Mar. 12, 2015; the entire contents of which are incorporated herein by reference.

### FIELD

Embodiments described herein relate generally to a solid-state imaging device and a method for manufacturing the same.

### BACKGROUND

Some solid-state imaging devices are provided with a prism disposed inside in order to separate color lights of red (R), green (G), and blue (B) from each other inside the device. For example, the prism is formed on a foundation layer having an inclined surface, and the foundation layer is manufactured using a photo engraving process (PEP) or the like. In the PEP, there is used a reticle called a grating mask.

However, in the foundation layer having the inclined surface, the top part having the greatest height steeply rises from a substrate of the solid-state imaging device. If such a part is processed using the grating mask, the corner part is rounded and the inclined surface having a sufficient size cannot be obtained in some cases. This phenomenon becomes conspicuous as miniaturization of pixels of the solid-state imaging device progresses. Failing to obtain the inclined surface with the sufficient size means decrease in an amount of light transmitted through the prism and the light reflected. As a result, the optical sensitivity of the solid-state imaging device problematically decreases.

### BRIEF DESCRIPTION OF THE DRAWINGS

FIG. 1A and FIG. 1B are schematic cross-sectional views showing a solid-state imaging device according to a first embodiment, wherein FIG. 1A is a schematic cross-sectional view at a position along the A-A′ line in FIG. 2, and FIG. 1B is a schematic cross-sectional view at a position along the B-B′ line in FIG. 2;

FIG. 2 is a schematic plan view showing a layout of lenses and light receiving sections of the solid-state imaging device according to the first embodiment;

FIG. 3A is a schematic plan view of a grating mask used in an exposure process for forming the solid-state imaging device according to the first embodiment, FIG. 3B is a graph showing an intensity distribution of the light transmitted through the grating mask, and FIG. 3C is a schematic cross-sectional view showing the state after a resist layer is irradiated with exposure light transmitted through the grating mask;

FIG. 4A is a schematic cross-sectional view showing the state after the resist layer is irradiated with the exposure light passed through the grating mask, and FIG. 4B is a schematic cross-sectional view showing the state after the resist layer is developed;

FIG. 5A and FIG. 5B are schematic perspective views showing a method for manufacturing the solid-state imaging device according to the first embodiment;

FIG. 6A and FIG. 6B are schematic perspective views showing a method for manufacturing the solid-state imaging device according to the first embodiment;

FIG. 7A and FIG. 7B are schematic cross-sectional views showing the method for manufacturing the solid-state imaging device according to the first embodiment;

FIG. 8A and FIG. 8B are schematic cross-sectional views showing the method for manufacturing the solid-state imaging device according to the first embodiment;

FIG. 9A and FIG. 9B are schematic cross-sectional views showing the method for manufacturing the solid-state imaging device according to the first embodiment;

FIG. 10A and FIG. 10B are schematic cross-sectional views showing the method for manufacturing the solid-state imaging device according to the first embodiment;

FIG. 11A and FIG. 11B are schematic perspective views showing a method for manufacturing a solid-state imaging device according to a reference example;

FIG. 12 is a schematic perspective view showing the method for manufacturing the solid-state imaging device according to the reference example;

FIG. 13A is a schematic plan view of a grating mask used in the exposure process for forming the solid-state imaging device according to the second embodiment, and FIG. 13B is a graph showing an example of an intensity distribution of the light transmitted through the grating mask;

FIG. 14 is a schematic perspective view showing the state after the resist layer is irradiated with the exposure light transmitted through the grating mask and then the resist layer is developed;

FIG. 15A to FIG. 15C are schematic cross-sectional views showing a method for manufacturing the solid-state imaging device according to the second embodiment;

FIG. 16A and FIG. 16B are schematic cross-sectional views showing the method for manufacturing the solid-state imaging device according to the second embodiment;

FIG. 17A and FIG. 17B are schematic cross-sectional views showing the method for manufacturing the solid-state imaging device according to the second embodiment; and

FIG. 18A and FIG. 18B are schematic cross-sectional views showing the method manufacturing for the solid-state imaging device according to the second embodiment.

### DETAILED DESCRIPTION

According to one embodiment, a solid-state imaging device includes a substrate; a first color light separation section; a first layer; a first light collecting section; a second color light separation section; a second layer; a second light collecting section. The substrate includes a first region receiving a first color light, a second region receiving the first color light, a third region receiving a second color light, and a fourth region receiving a third color light. The first color light separation section is provided on the first region, the first color light separation section has a first inclined surface, an angle of the first inclined surface to a horizontal direction on the substrate is a first angle. The first layer is provided on the first color light separation section. The first light collecting section is provided above the first region. The second color light separation section is provided on the second region, the second color light separation section has a second inclined surface, an angle of the second inclined surface to the horizontal direction on the substrate is a second angle. The second layer is provided on the second color light separation section. The second light collecting section is provided above the second region.

Various embodiments will be described hereinafter with reference to the accompanying drawings. In the description presented hereinafter, the same members are denoted with the same reference symbols, and the description of the members presented once will arbitrarily be omitted.

### First Embodiment

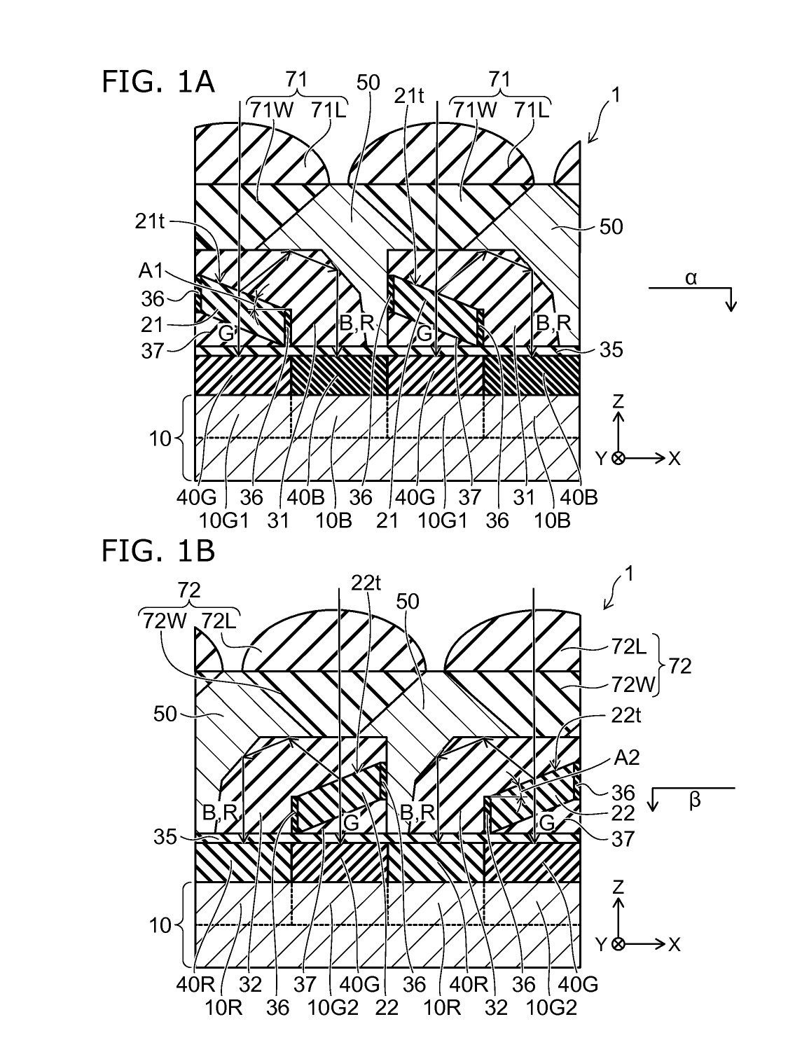

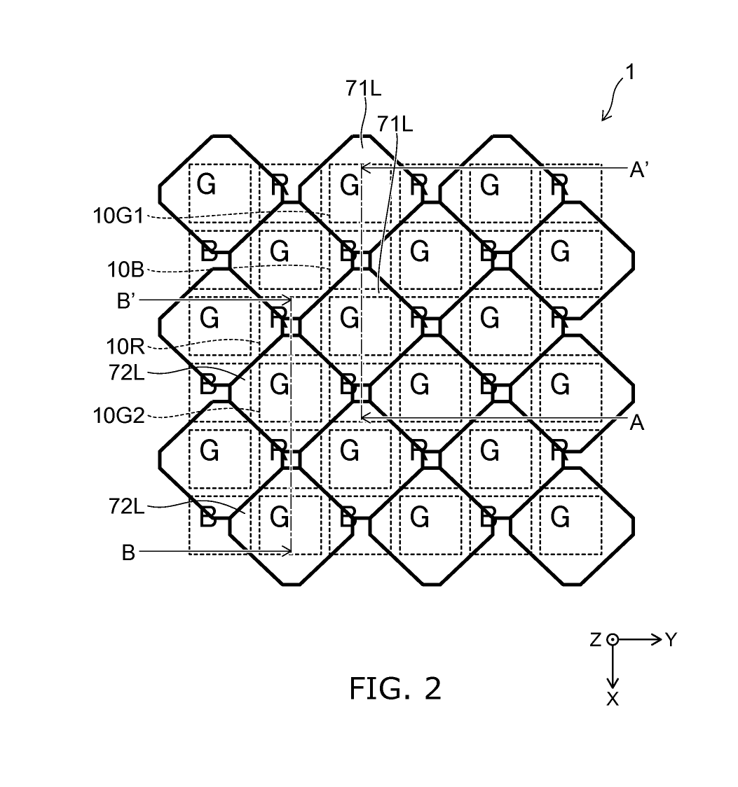

FIG. 1A and FIG. 1B are schematic cross-sectional views showing a solid-state imaging device according to the first embodiment, wherein FIG. 1A is a schematic cross-sectional view at a position along the A-A′ line in FIG. 2, and FIG. 1B is a schematic cross-sectional view at a position along the B-B′ line in FIG. 2.

FIG. 2 is a schematic plan view showing a layout of lenses and light receiving sections of the solid-state imaging device according to the first embodiment.

The solid-state imaging device 1 according to the first embodiment includes a substrate 10 having first light receiving regions (hereinafter referred to as light receiving regions 10G1), second light receiving regions (hereinafter referred to as light receiving regions 10G2), third light receiving regions (hereinafter referred to as light receiving regions 10B), and fourth light receiving regions (hereinafter referred to as light receiving regions 10R), first light collecting sections (hereinafter referred to as light collecting sections 71), first color light separation sections (hereinafter referred to as color light separation sections 21), first waveguide sections (hereinafter referred to as waveguide sections 31), second light collecting sections (hereinafter referred to as light collecting sections 72), second color light separation sections (hereinafter referred to as color light separation sections 22), and second waveguide sections (hereinafter referred to as waveguide sections 32). Further, the solid-state imaging device 1 includes color filters 40G, 40B, and 40R, a metal layer 50, insulating films 35, 36, and an insulating layer 37 (FIGS. 1A and 1B).

The substrate 10 is, for example, a semiconductor substrate. The semiconductor substrate includes silicon (Si). On the upper surface of the substrate 10, there are provided the light receiving regions 10G1, 10G2, 10B and 10R. The light receiving regions 10G1 and the light receiving regions 10G2 are each capable of receiving a first color light (hereinafter referred to as a green light (G)). The light receiving regions 10B are each capable of receiving a second color light (hereinafter referred to as a blue light (B)). The light receiving regions 10R are each capable of receiving a third color light (hereinafter referred to as a red light (R)).

Each of the light receiving regions 10G1, the light receiving regions 10G2, the light receiving regions 10B, and the light receiving regions 10R are disposed in an array (FIG. 2). Pixels of the solid-state imaging device 1 has so-called Bayer array, for example. The Bayer array has a structure that, when four pixels are made one set, two pixels for green (G) are arrayed in a first diagonal direction, and a pixel for blue (B) and a pixel for red (R) are arrayed in a second diagonal direction. Here, the first diagonal direction crosses the second diagonal direction. The solid-state imaging device 1 is a part of, for example, a digital camera, a camera applied to a cellular phone and so on.

In particular, a direction from the light receiving region 10G1 toward the light receiving region 10B and a direction from the light receiving region 10G2 toward the light receiving region 10R are opposite to each other. For example, the light receiving region 10B is provided adjacent to the light receiving region 10G1 in an X-direction. In other words, the light receiving region 10G1 and the light receiving region 10B are arranged side by side in the X-direction (a first direction). The light receiving region 10R is provided adjacent to the light receiving region 10G2 in the X-direction. In other words, the light receiving region 10G2 and the light receiving region 10R are arranged side by side in the X-direction. The light receiving region 10B is provided adjacent to the light receiving region 10G2 in a direction (a Y-direction) crossing the direction (the X-direction) from the light receiving region 10G1 toward the light receiving region 10B. In other words, the light receiving region 10G2 and the light receiving region 10B are arranged side by side in the Y-direction. The light receiving region 10R is provided adjacent to the light receiving region 10G1 in a direction (e.g., the Y-direction) crossing the direction (e.g., the X-direction) from the light receiving region 10G2 toward the light receiving region 10R. In other words, the light receiving region 10G1 and the light receiving region 10R are arranged side by side in the Y-direction crossing the X-direction.

The light receiving regions 10G1, 10G2, 10B, and 10R include a photoelectric conversion element for converting the light into an electric signal. The photoelectric conversion element includes, for example, a photodiode containing silicon. The light receiving regions 10G1, 10G2 each detect, for example, the green light. The light receiving regions 10B each detect, for example, the blue light. The light receiving regions 10R each detect, for example, the red light. Further, in the solid-state imaging device 1, a region consisting of only one light receiving region out of the light receiving regions 10G1, 10G2, 10B, and 10R is defined as a pixel.

The color light separation sections 21 are provided on the substrate 10. The color light separation sections 21 are each provided between, for example, the substrate 10 and the light collecting section 71. The color light separation section 21 has a dichroic mirror preferentially transmitting, for example, the green light. For example, in the color light separation section 21, the light transmittance of the green light is higher than the light transmittance of the blue light and the light transmittance of the red light. The dichroic mirror is a multilayer film having layers each including a high refractive index material (e.g., a titanium oxide (TiO₂)) and layers each including a low refractive index material (e.g., a silicon oxide (SiO₂)) stacked alternately. For example, the dichroic mirror transmits, for example, the green light in a range of 490 nm through 580 nm, and reflects the blue light in a range equal to or shorter than 490 nm and the red light in a range equal to or longer than 580 nm. Further, it is also possible to provide a layer including a silicon nitride (Si₃N₄) on the outermost surface of the dichroic mirror.

The color light separation section 21 has a first inclined surface (hereinafter referred to as a inclined surface 211) irradiated with the green light, the blue light, and the red light. An angle of the inclined surface 21t to a horizontal direction on the substrate 10 is defined as a first angle A1 (0 degree<A1<90 degree). The inclined surface 21t is disposed on the light receiving region 10G1. The green light is transmitted through the inclined surface 21t. The blue light or the red light is reflected by the inclined surface 21t.

The waveguide section 31 is provided on the color light separation section 21 and the substrate 10. The waveguide section 31 is provided between the color light separation section 21 or the substrate 10, and the light collecting section 71. The blue light or the red light reflected by the inclined surface 21t is guided to the light receiving region 10B by the waveguide section 31. For example, the blue light or the red light is totally reflected inside the waveguide section 31, and is guided to the light receiving region 10B. The waveguide section 31 includes a silicon oxide (SiO₂).

The light collecting section 71 is provided on the waveguide section 31. The light collecting section 71 has a convex lens 71L, and a waveguide 71W, including a silicon oxide (SiO₂) for example, provided under the lens 71L. The light collecting section 71 collects the green light, the blue light, and the red light, which have entered the lens 71L, toward the color light separation section 21. The waveguide 71W guides the light, which is collected by the lens 71L, toward the color light separation section 21. In the case of viewing the lens 71L from above, the lens 71L has a shape of, for example, a square with rounded corners.

The lens 71L is disposed on the center of the light receiving region 10G1, or disposed so that the light passed through the lens converges on the center of the light receiving region 10G1. The range in which the lens 71L is disposed covers a light receiving surface of the light receiving region 10G1, a part of the light receiving surface of the light receiving region 10B adjacent to the light receiving region 10G1 in the X-direction, and a part of the light receiving surface of the light receiving region 10R adjacent to the light receiving region 10G1 in the Y-direction. For example, the area of the lens 71L viewed from above roughly corresponds to the area of two pixels. In other words, in the solid-state imaging device 1, there is adopted a structure in which each of the lenses 71L corresponds to a combination of the light receiving regions 10G1, 10B, and 10R. Such a structure of the lenses is the same as in the lenses 72L described later.

The color light separation sections 22 are provided on the substrate 10. The color light separation sections 22 each have the dichroic mirror described above. The color light separation section 22 has a second inclined surface (hereinafter referred to as a inclined surface 22t) irradiated with the green light, the blue light, and the red light. An angle of the inclined surface 22t to the horizontal direction on the substrate 10 is defined as a second angle A2 (0 degree<A2<90 degree). The inclined surface 22t is disposed on the light receiving region 10G2. The green light is transmitted through the inclined surface 22t, and the blue light or the red light is reflected by the inclined surface 22t.

The waveguide section 32 is provided on the color light separation section 22 and the substrate 10. The blue light or the red light reflected by the inclined surface 22t is guided to the light receiving region 10R by the waveguide section 32. For example, the blue light or the red light is totally reflected inside the waveguide section 32, and is guided to the light receiving region 10R. The waveguide section 32 includes a silicon oxide (SiO₂).

The light collecting section 72 is disposed on the waveguide section 32. The green light, the blue light, and the red light are collected in the color light separation section 22 by the light collecting section 72. The light collecting section 72 has a convex lens 72L, and a waveguide 72W, including a silicon oxide (SiO₂) for example, provided under the lens 72L. The waveguide 72W guides the light, which is collected by the lens 72L, to the color light separation section 22. In the case of viewing the lens 72L from above, the lens 72L has a shape of, for example, a square with rounded corners.

In the solid-state imaging device 1, a direction (the arrow a) in which the blue light or the red light is guided from the color light separation section 21 to the light receiving region 10B, and a direction (the arrow β) in which the blue light or the red light is guided from the color light separation section 22 to the light receiving region 10R are opposite to each other.

In the solid-state imaging device 1, first filters (hereinafter referred to as color filters 40G) are each provided between the light receiving region 10G1 and the color light separation section 21 and between the light receiving region 10G2 and the color light separation section 22. Second filters (hereinafter referred to as color filters 40B) are each provided between the light receiving region 10B and the waveguide section 31. Third filters (hereinafter referred to as color filters 40R) are each provided between the light receiving region 10R and the waveguide section 32.

In the case of viewing the color filters 40G, 40B, and 40R from above, the color filters 40G, 40B, and 40R each have, for example, a square shape. In the color filter 40G, the transmittance with respect to the green light is higher than the transmittance with respect to the blue light and the red light. The color filters 40G, 40B, and 40R each include, for example, organic resin.

In the color filter 40B, the transmittance with respect to the blue light is higher than the transmittance with respect to the green light and the red light. For example, even if the blue light or the red light is guided to the light receiving region 10B by the waveguide section 31, the red light is shielded by the color filter 40B, and the blue light preferentially reaches the light receiving region 10B. In the color filter 40R, the transmittance with respect to the red light is higher than the transmittance with respect to the green light and the blue light. For example, even if the blue light or the red light is guided to the light receiving region 10R by the waveguide section 32, the blue light is shielded by the color filter 40R, and the red light preferentially reaches the light receiving region 10R.

In the solid-state imaging device 1, it is possible to adopt a structure not provided with the color filters 40G, 40B, and 40R. For example, it is possible for the color light separation section 21 including the dichroic mirror to preferentially transmit the green light, preferentially absorb the red light, and preferentially reflect the blue light. Further, it is possible for the color light separation section 22 including the dichroic mirror to preferentially transmit the green light, preferentially absorb the blue light, and preferentially reflect the red light.

In the solid-state imaging device 1, the metal layer 50 is provided on the waveguide sections 31, 32. The metal layer 50 functions as a reflecting mirror for reflecting the light proceeding through the transparent waveguide sections 31, 32. The metal layer 50 includes, for example, aluminum (Al) or silver (Ag). In the solid-state imaging device 1, the insulating film 35 is provided between the color filter 40G and the color light separation section 21, between the color filter 40B and the waveguide section 31, between the color filter 40G and the color light separation section 22, and between the color filter 40R and the waveguide section 32. A structure replacing the metal layer 50 with a gap is also included in the embodiment. In this case, the gap is filled with air or the like.

In the solid-state imaging device 1, the insulating films 36 are provided on side walls of each of the color light separation sections 21, 22. The insulating films 35, 36 each include, for example, a silicon nitride (Si₃N₄) or a silicon oxide (SiO₂). For example, by changing the refractive index of the color light separation section 22 and the refractive index of the insulating films 36, total reflection or nearly total reflection of the light becomes easy to occur in a boundary between the color light separation section 22 and each of the insulating films 36. Thus, the green light is efficiently collected in each of the light receiving regions 10G1, 10G2.

In the solid-state imaging device 1, the insulating layer 37 is provided under the color light separation sections 21, 22. The insulating layer 37 is a transparent layer, and is a support member of the color light separation sections 21, 22. The insulating layer 37 includes, for example, a silicon nitride (Si₃N₄) or a silicon oxide (SiO₂).

Proceeding of the light entering the lenses will be described using FIG. 1A as an example. FIG. 1A schematically shows a path of the lights entering the lense 71L using the arrows G, B, and R.

For example, in the example shown in FIG. 1A, the light, which includes the green light (G), the blue light (B), and the red light (R), and has entered the lens 71L, is collected by the lens 71L of the light collecting section 71, and is further converged by the waveguide 71W of the light collecting section 71. The light is emitted from the light collecting section 71 toward the color light separation section 21 via the waveguide section 31.

The color light separation section 21 transmits the green light, and reflects the blue light and the red light. The green light transmitted through the color light separation section 21 proceeds straight to the light receiving region 10G1, and is converted by the photoelectric conversion element into a charge. The blue light and the red light reflected by the color light separation section 21 are bent in light path, and proceed toward the metal layer 50 (the reflecting mirror). The blue light and the red light proceeding toward the metal layer 50 are totally reflected inside the waveguide section 31 repeatedly a plurality of times, and then proceed toward the light receiving region 10B. Among the blue light and the red light proceeding toward the light receiving region 10B, the red light is shielded by the color filter 40B. The blue light entering the light receiving region 10B is converted by the photoelectric conversion element B into a charge.

FIG. 1B also shows schematically a path of the lights entering the lense 71L using the arrows G, B, and R. In FIG. 1B, the green light transmitted through the color light separation section 22 proceeds straight to the light receiving region 10G2, and is converted by the photoelectric conversion element into a charge. Further, the red light entering the light receiving region 10R is converted by the photoelectric conversion element B into a charge.

A manufacturing process of the solid-state imaging device 1 will be described.

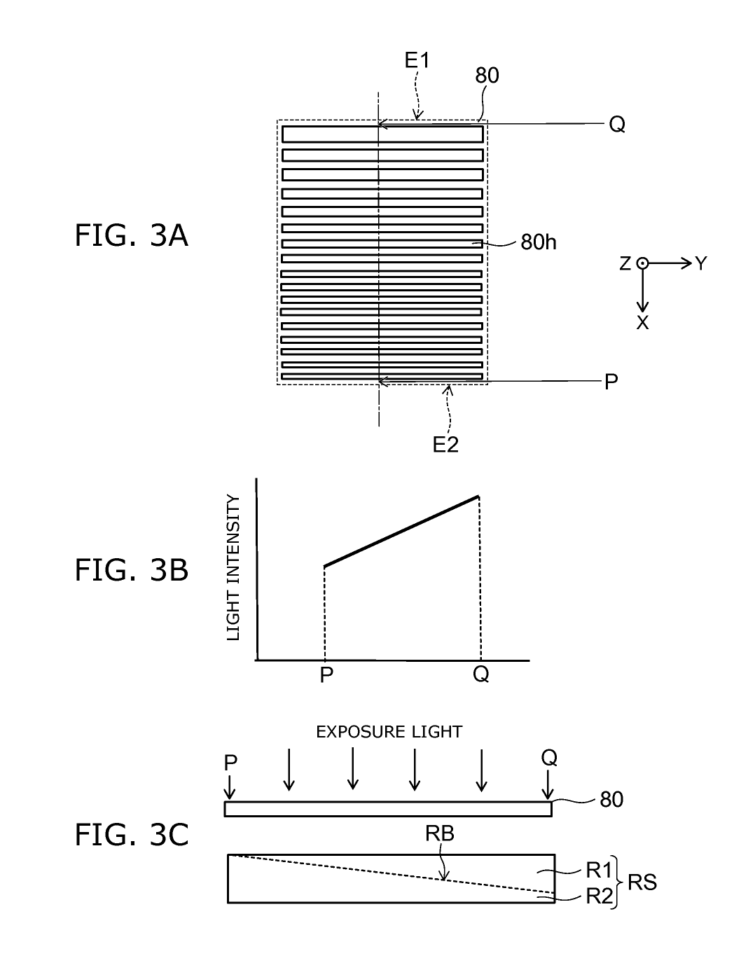

FIG. 3A is a schematic plan view of a grating mask used in an exposure process for forming the solid-state imaging device according to the first embodiment, FIG. 3B is a graph showing an intensity distribution of the light transmitted through the grating mask, and FIG. 3C is a schematic cross-sectional view showing the state after a resist layer is irradiated with exposure light transmitted through the grating mask.

The grating mask 80 (a mask) shown in FIG. 3A is used when, for example, exposing the pixels. The grating mask 80 shown in FIG. 3A is a minimum unit of the grating mask. In the grating mask 80, the minimum units are arranged in the X-direction and the Y-direction in a repeated manner. It should be noted that in the grating mask related to the first embodiment, a direction from a position P to a position Q is reversed between the minimum units adjacent to each other in, for example, the X-direction (described later). Due to the grating mask 80, the entire wafer can be exposed. As shown in FIG. 3A, the grating mask 80 includes a plurality of transparent sections 80h each having a stripe shape and arranged side by side in parallel to each other. The grating mask 80 has a structure including the transparent sections 80h and line sections (light shielding sections) other than the transparent sections 80h. In the minimum unit, an end E1 faces an end E2. The density of the pattern (the line sections) for shielding the exposure light continuously decreases in a direction from the end E1 toward the end E2. For example, the widths of the plurality of transparent sections 80h increase in a direction from the position P toward the position Q. Then, a distance between an adjacent patterns shielding the exposure light decreases from the P position toward the Q position gradually. It should be noted that each of the transparent sections 80h is not required to have a stripe shape, but can also include a structure in which a plurality of circular transparent sections are arranged along a stripe to form a line. In this case, the diameter of the circle increases in a direction from the position P toward the position Q.

When the exposure light is transmitted through such a mask, the intensity of the exposure light transmitted increases in a direction from the position P toward the position Q in the minimum unit (FIG. 3B). As the exposure light, there is used, for example, an i-line.

FIG. 3C shows the state after a positive resist layer RS, for example, is irradiated with the exposure light transmitted through the grating mask 80 in the minimum unit. In the resist layer RS, the intensity of the exposure light received increases in a direction from the position P toward the position Q. Thus, the thickness of an exposed portion R1 from the surface becomes small at the position P, and the thickness of the exposed portion R1 from the surface becomes large at the position Q. Therefore, between the exposed portion R1 and an unexposed portion R2 under the exposed portion R1, there is formed a boundary surface RB inclined with respect to the foundation. For example, in the example shown in FIG. 3C, the boundary surface RB between the exposed portion R1 and the unexposed portion R2 becomes a negative slope. In other words, by using the grating mask 80 and removing the exposed portion R1 by development, the resist layer RS having a inclined surface as the upper surface is formed.

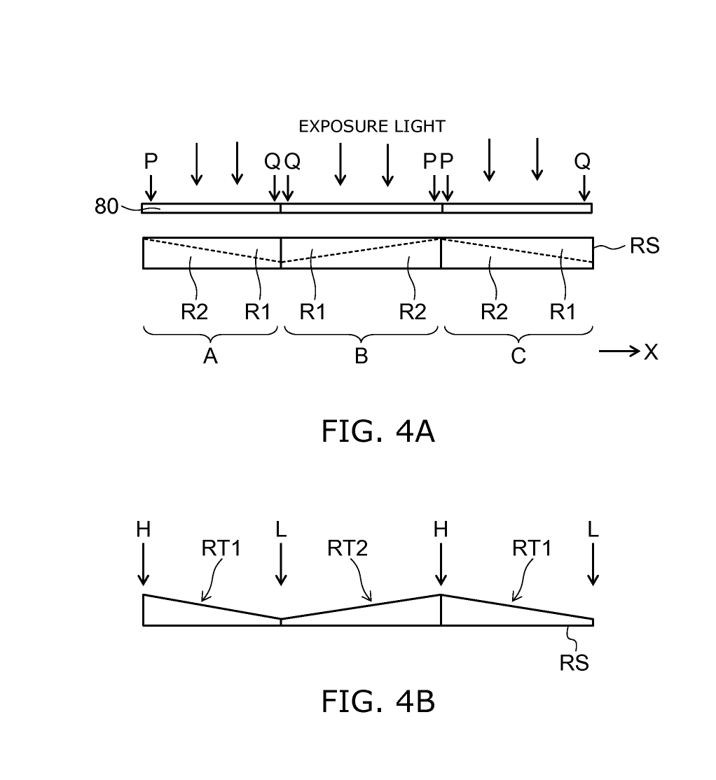

FIG. 4A is a schematic cross-sectional view showing the state after the resist layer is irradiated with the exposure light passed through the grating mask, and FIG. 4B is a schematic cross-sectional view showing the state after the resist layer is developed.

For example, as shown in FIG. 4A, the grating mask 80 having the position P and the position Q reversed between the minimum units adjacent to each other is disposed on the upper side of the positive resist layer RS. Then, the positive resist layer RS is irradiated with the exposure light through the grating mask 80.

Subsequently, the resist layer RS is developed. Thus, the resist layer RS is patterned. The resist layer RS, on which the development is performed, include peaks and troughs. FIG. 4B shows this state.

For example, the resist layer RS has inclined surfaces RT1 and inclined surfaces RT2, and positions where the inclined surface RT1 and the inclined surface RT2 are connected to each other have the smallest thickness of the resist layer RS (the positions indicated by the arrows L) or the greatest thickness (the positions indicated by the arrows H). The smallest thickness is defined as minimal thickness, the greatest thickness is defined as maximal thickness in the embodiments.

As described above, in the first embodiment, the grating mask 80 is used, the intensity of exposure light transmitted through the mask increasing in a direction from the position where the resist layer RS has the greatest thickness toward the position where the resist layer RS has the smallest thickness in the grating mask 80.

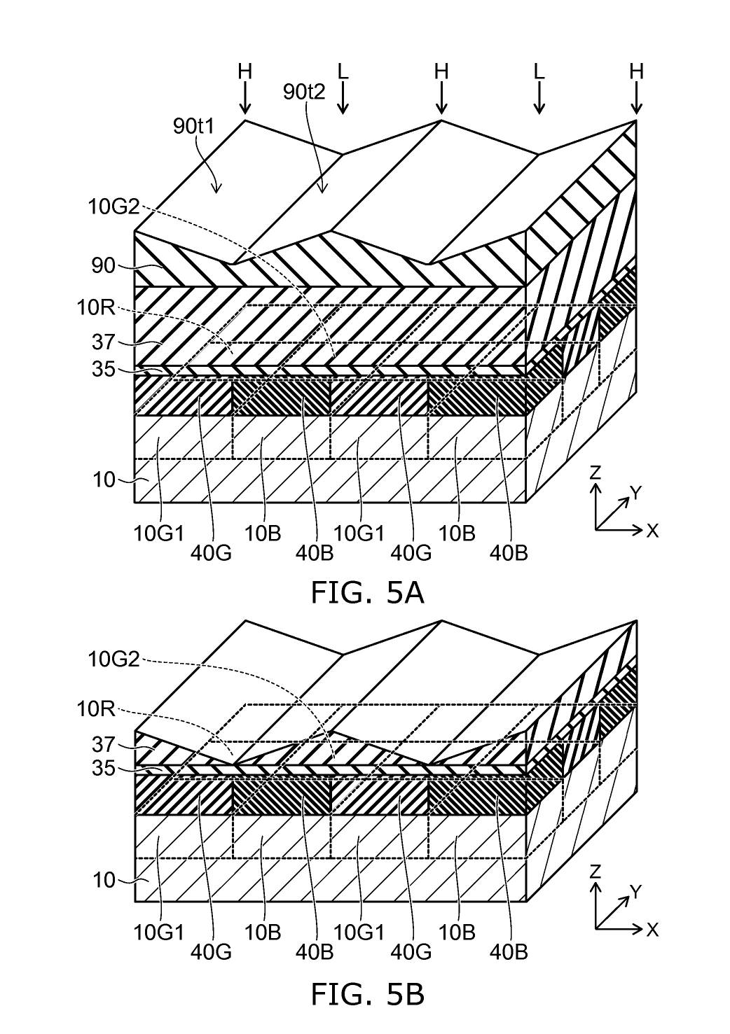

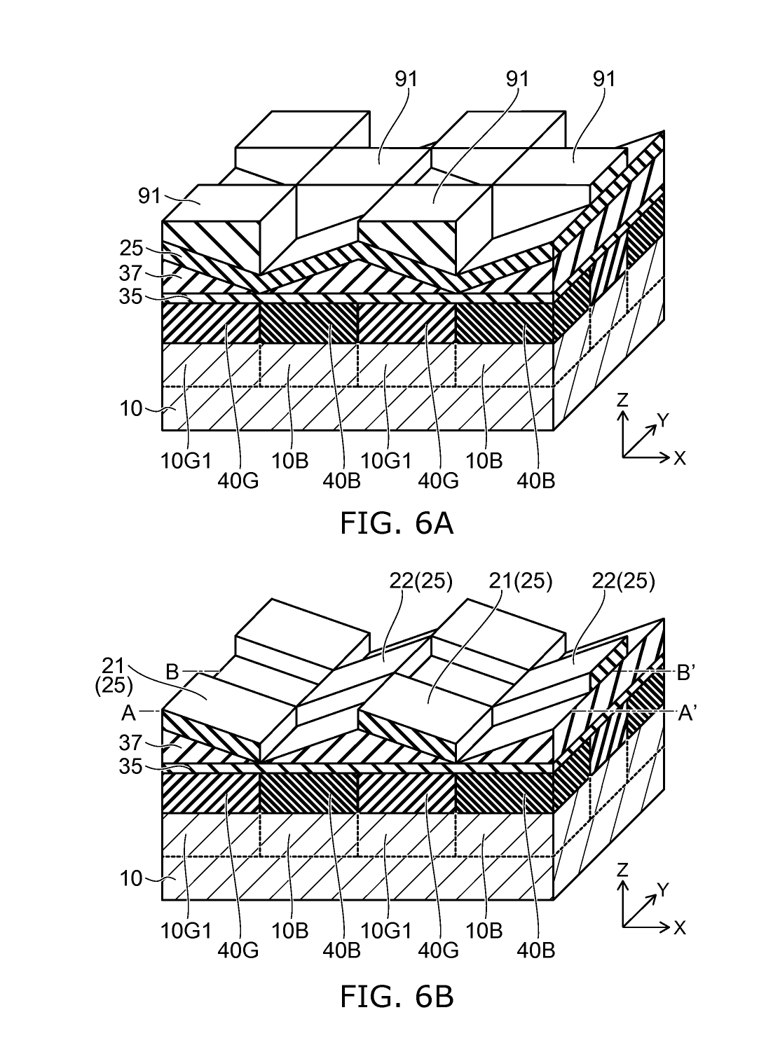

FIG. 5A through FIG. 6B are schematic perspective views showing a method for manufacturing the solid-state imaging device according to the first embodiment.

For example, as shown in FIG. 5A, the color filters 40G, 40B, and 40R are formed on the substrate 10 provided with the light receiving regions 10G1, 10G2, 10B, and 10R. The light receiving region 10G2 is positioned in the back or in front of the light receiving region 10B in the Y-direction.

The light receiving region 10R is positioned in the back or in front of the light receiving region 10G1 in the Y-direction. The color filter 40R is positioned in the back or in front of the color filter 40G in the Y-direction although not shown in the drawings.

Subsequently, the insulating film 35 is formed on the color filters 40G, 40B, and 40R.

Subsequently, a first insulating layer (the insulating layer 37) is formed on the insulating film 35.

Subsequently, a positive resist layer 90 is applied on the insulating layer 37. Then, the resist layer 90 is irradiated with the exposure light through the grating mask 80. Subsequently, the resist layer 90 is developed. Thus, the resist layer 90 is patterned. The peaks and the troughs are formed on the surface of the resist layer 90.

For example, as shown in FIG. 5A, the resist layer 90, having the first inclined surfaces (hereinafter referred to as, for example, inclined surfaces 90t1) on the light receiving regions 10G1 and the light receiving regions 10R, and the second inclined surfaces (hereinafter referred to as, for example, 90t2) on the light receiving regions 10G2 and the light receiving regions 10B. In the resist layer 90, the positions where the inclined surface 90t1 and the inclined surface 90t2 are connected to each other have the smallest thickness (in the positions indicated by the arrows L) of the thickness of the resist layer 90, or the greatest thickness (in the positions indicated by the arrows H). In other words, the resist layer 90 has a thinnest position H and a thickest position L, the inclined surface 90t1 is in contact with the inclined surface 90t2 at the thinnest position L and the thickest position H. Further, the inclined surfaces 90t1 and the inclined surfaces 90t2 each extend continuously in the Y-direction. The resist layer 90 having such a surface shape is formed on the insulating layer 37. An angle between the inclined surface 90t1 and the inclined surface 90t2 is an obtuse angle.

As described above, the inclined surfaces 90t1 are formed on the light receiving regions 10G1 and the light receiving regions 10R, and the inclined surfaces 90t2 are formed on the light receiving regions 10G2 and the light receiving regions 10B so that the positions where the inclined surface 90t1 and the inclined surface 90t2 are connected to each other have the smallest thickness or the greatest thickness of the thickness of the resist layer 90. The resist layer 90 has the inclined surfaces 90t1 positioned on the light receiving regions 10G1 or the light receiving regions 10R, and the inclined surfaces 90t2 positioned on the light receiving regions 10G2 or the light receiving regions 10B.

Subsequently, the surface of the resist layer 90 is etched back using, for example, reactive ion etching (RIE) to partially expose a surface of the insulating layer 37 from the resist layer 90. Subsequently, the RIE is continued to remove the resist layer 90 by the etchback (etching) process. Further, the surface of the insulating layer 37 thus exposed is etched back using the RIE to thereby transfer the surface shape (the shape of the peaks and the troughs) of the resist layer 90 described above having the inclined surfaces 90t1 and the inclined surfaces 90t2 to the surface of the insulating layer 37. FIG. 5B shows this state.

Then, as shown in FIG. 6A, a multilayer film 25 is formed on the insulating layer 37 to which the surface shape is transferred. The multilayer film 25 has the same laminate structure as that of the color light separation section 21 or the color light separation section 22. Subsequently, a mask layer 91 is selectively formed on the multilayer film 25 provided on an upper side of the light receiving regions 10G1, 10G2.

Then, unnecessary portions of the multilayer film 25 are removed by a PEP process. For example, the multilayer film 25 on the light receiving regions 10B and the light receiving regions 10R is selectively removed using an RIE process. Subsequently, the mask layer 91 is removed. FIG. 6B shows this state.

Due to the RIE process, the multilayer film 25 is divided into a plurality of regions. The multilayer film 25 provided on the light receiving regions 10G1 corresponds to the color light separation sections 21 described above, and the multilayer film 25 provided on the light receiving regions 10G2 corresponds to the color light separation sections 22 described above.

Hereinafter, the subsequent manufacturing process will be described, wherein the multilayer film 25 thus separated is referred to as the color light separation sections 21 or the color light separation sections 22.

Further, the subsequent manufacturing process will be described using cross-sectional views instead of the perspective views. For example, the description will be presented showing cross-sectional views parallel to the X-Z plane including the A-A′ line shown in FIG. 6B and cross-sectional views parallel to the X-Z plane including the B-B′ line at the same time as an example.

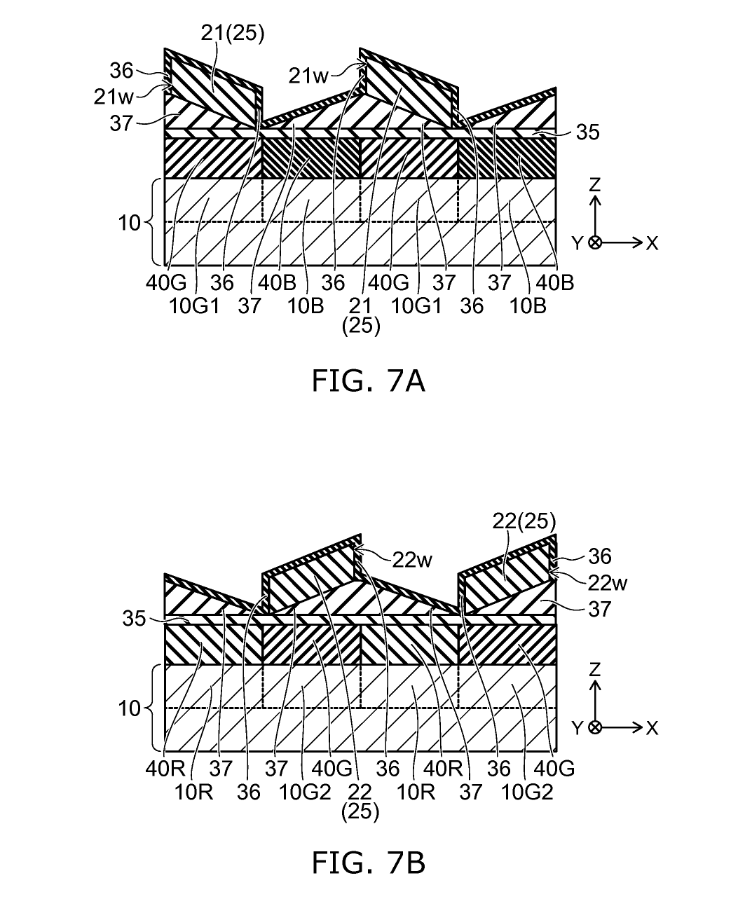

FIG. 7A through FIG. 10B are schematic cross-sectional views showing the method for manufacturing the solid-state imaging device according to the first embodiment.

Further, among FIG. 7A through FIG. 10B, FIGS. 7A, 8A, 9A, and 10A each correspond to a cross-sectional surface in the X-Z plane including the A-A′ line shown in FIG. 6B, and FIGS. 7B, 8B, 9B, and 10B each correspond to a cross-sectional surface in the X-Z plane including the B-B′ line.

As shown in FIG. 7A and FIG. 7B, the insulating film 36, for example, is formed on the insulating layer 37 and the multilayer film 25.

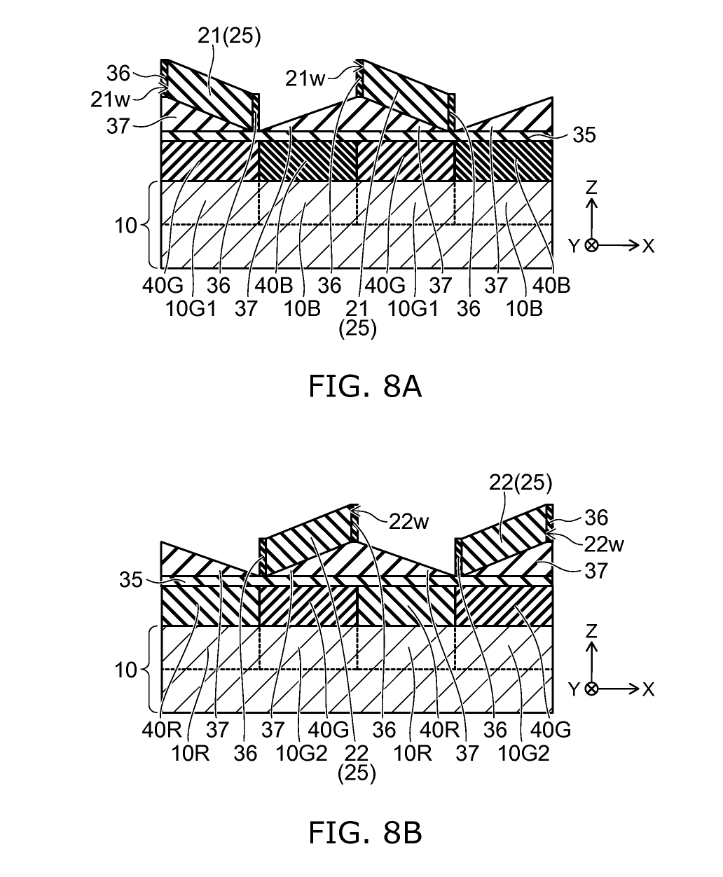

Then, as shown in FIG. 8A and FIG. 8B, the RIE process is performed on the insulating film 36 to thereby remove the insulating film 36 except the portions having contact with side walls 21w of the color light separation sections 21 or side walls 22w of the color light separation sections 22.

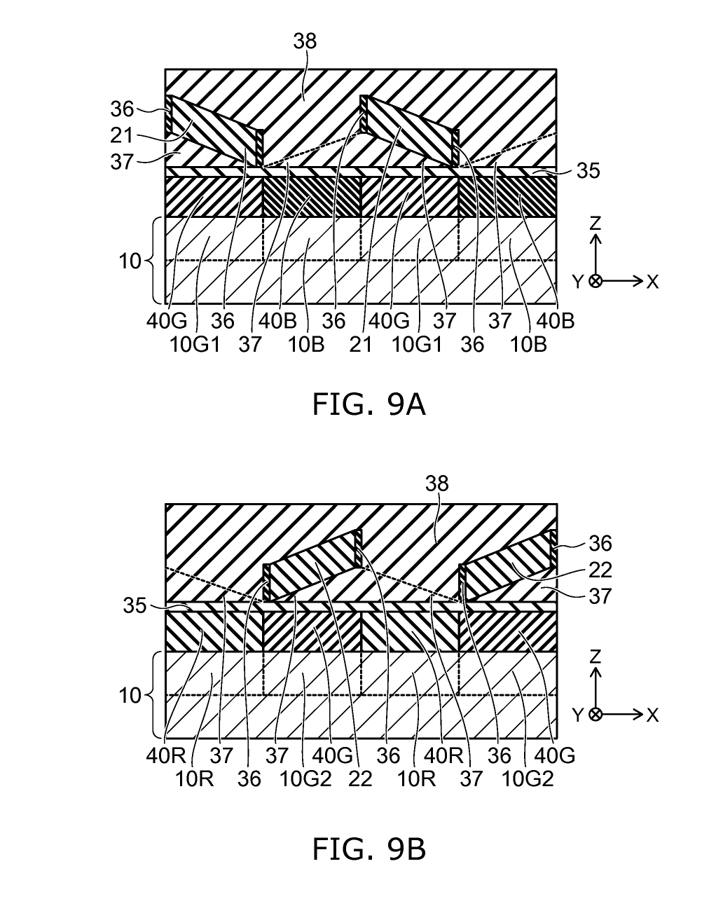

Then, as shown in FIG. 9A and FIG. 9B, a second insulating layer (hereinafter referred to as, for example, an insulating layer 38) is formed on the insulating layer 37 and the color light separation sections 21, 22.

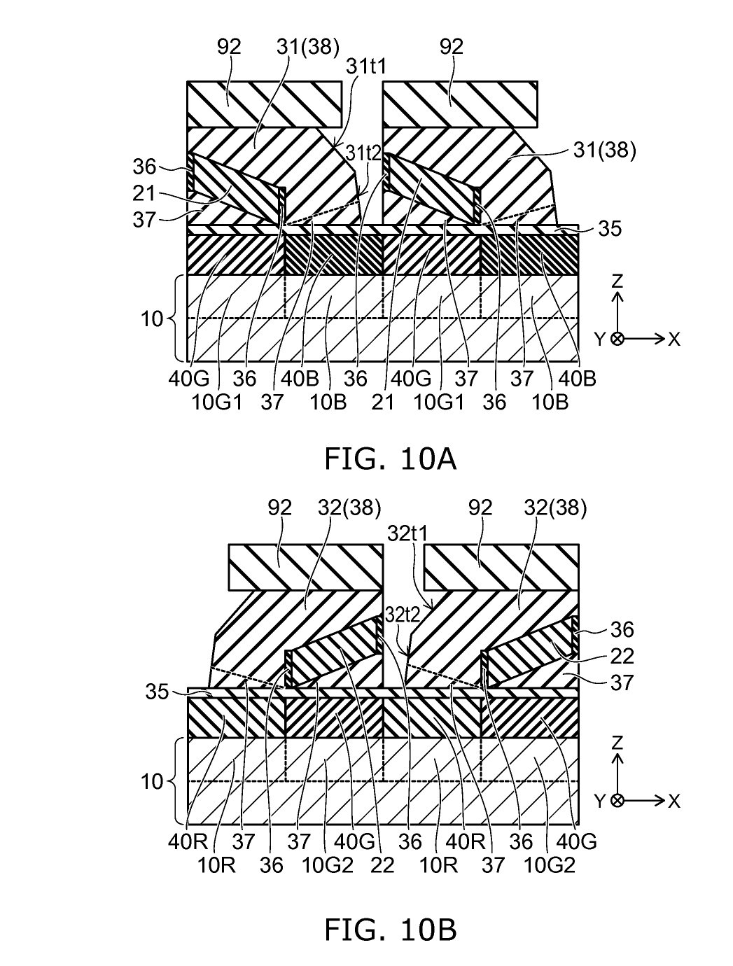

Subsequently, as shown in FIG. 10A and FIG. 10B, a mask layer 92 is selectively formed on the insulating layer 38. Subsequently, the insulating layer 38 is separated using anisotropic etching such as RIE and isotropic etching in combination with each other. For example, the insulating layer 38 is selectively formed on the light receiving region 10G1 and the light receiving region 10B, and on the light receiving region 10G2 and the light receiving region 10R. Hereinafter, the subsequent manufacturing process will be described, wherein the insulating layer 38 thus separated is referred to as the waveguide sections 31 or the waveguide sections 32.

The waveguide sections 31 are each formed on the light receiving region 10G1 and the light receiving region 10B, and the waveguide sections 32 are each formed on the light receiving region 10G2 and the light receiving region 10R. Here, the insulating layer 37 under the insulating layer 38 forms a part of the waveguide section 31 or the waveguide section 32. In the case in which the material of the insulating layer 37 is the same as the material of the insulating layer 38, the waveguide section 31 or the waveguide section 32 becomes a layer having homogenous or roughly homogenous refractive index.

Further, each of inclined surfaces 31t1, 31t2 provided to the waveguide section 31 is arbitrarily adjusted in angle by adjusting etching conditions. Further, each of inclined surfaces 32t1, 32t2 provided to the waveguide section 32 is arbitrarily adjusted in angle by adjusting the etching conditions. Subsequently, the mask layer 92 is removed.

Subsequently, as shown in FIGS. 1A and 1B, the metal layer 50 is formed on the waveguide sections 31 each provided on the light receiving region 10G1 and the light receiving region 10B, and on the waveguide sections 32 each provided on the light receiving region 10G2 and the light receiving region 10R. Further, the metal layer 50 is selectively etched to form the waveguides 71W, 72W. Subsequently, the lenses 71L, 72L are formed.

Before describing advantages of the solid-state imaging device 1 according to the first embodiment, a solid-state imaging device according to a reference example will be described.

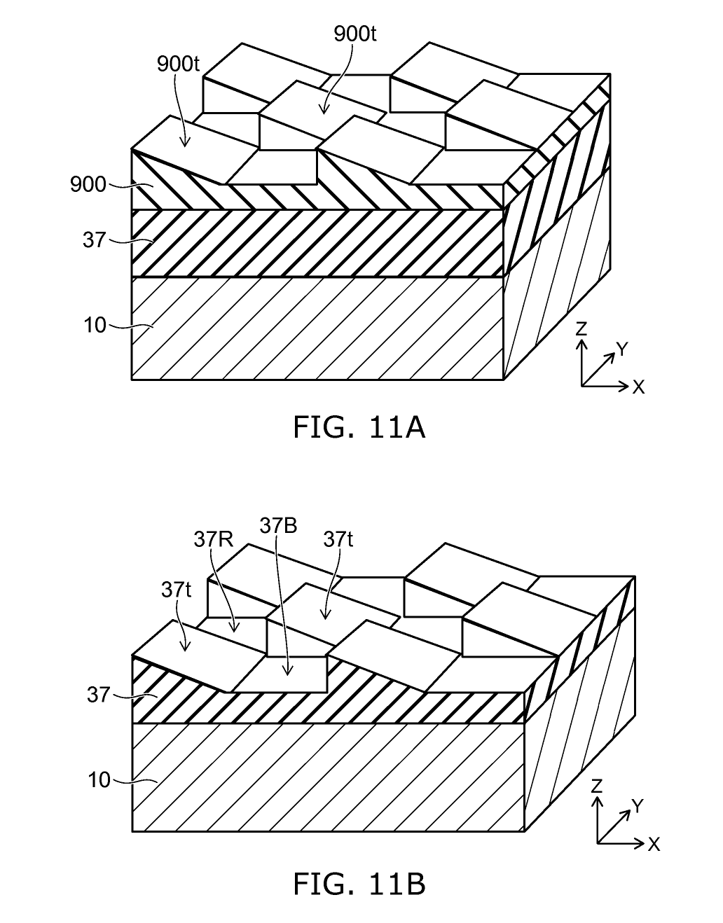

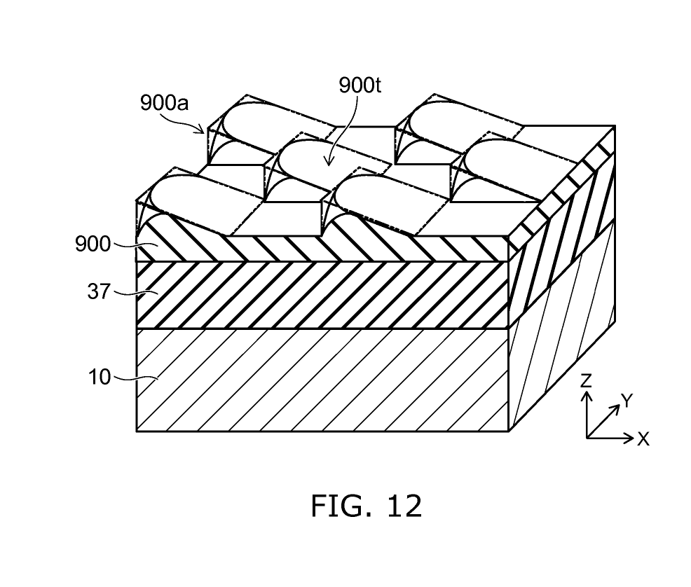

FIG. 11A, FIG. 11B, and FIG. 12 are schematic perspective views showing a method for manufacturing the solid-state imaging device according to the reference example.

As shown in FIG. 11A, a resist layer 900 is also patterned on the insulating layer 37 in the reference example. In the reference example, the grating mask is also used in a PEP process for forming the resist layer 900. However, in the reference example, regarding the grating mask, the position P and the position Q are not reversed unlike the first embodiment. In the reference example, in the resist layer 900 on which the development is performed, a plurality of inclined surfaces 900t are separated in the X-direction and the Y-direction. Further, after the development, in the resist layer 900, the phase of the inclined surfaces 900t aligned in the X-direction in one column and the phase of the inclined surfaces 900t aligned in the X-direction in another column adjacent to the one column in the Y-direction are shifted as much as 180° from each other. In other words, in the reference example, the resist layer 900 is patterned so that the plurality of inclined surfaces 900t face to the same direction.

FIG. 11B shows the state after the surface shape of the resist layer 900 is transferred to the insulating layer 37 as a foundation layer using the RIE process.

As shown in FIG. 11B, in the insulating layer 37 to which the surface shape of the resist layer 900 is transferred, the inclined surfaces 37t are also separated from each other in the X-direction and the Y-direction. Further, the phase of the inclined surfaces 37t aligned in the X-direction in one column and the phase of the inclined surfaces 37t aligned in the X-direction in another column adjacent to the one column in the Y-direction are shifted as much as 180° from each other. Further, the plurality of inclined surfaces 37t face to the same direction.

In the reference example, it is also possible to provide a dichroic mirror on the inclined surface 37t of the insulating layer 37, and to dispose the light receiving region 10G1 (or 10G2) on the lower side of the inclined surface 37t. Further, it is also possible to dispose the light receiving region 10B on the lower side of a region 37B adjacent to the inclined surface 37t, and to dispose the light receiving region 10R on the lower side of a region 37R adjacent to the inclined surface 37t.

By adopting such a configuration, it is possible to dispose, for example, the lens 71L on the light receiving surface of the light receiving region 10G1, a part of the light receiving surface of the light receiving region 10B adjacent to the light receiving region 10G1 in the X-direction, and a part of the light receiving surface of the light receiving region 10R adjacent to the light receiving region 10G1 in the Y-direction. In other words, in the reference example, it is also possible to form the solid-state imaging device in which each of the lenses 71L corresponds to one combination of the light receiving regions 10G1, 10B, and 10R.

However, the surface shape of the resist layer 900 after the development is performed fails to have the shape shown in FIG. 11A in some cases. For example, FIG. 12 shows an example of the surface shape of the resist layer 900 after the development is performed.

For example, a part 900a (e.g., a part rising roughly vertically in the Z-direction) of the resist layer 900 steeply rising fails to have an acute angle in some cases. In other words, tip portions of the resist layer 900 each have a gentle curved surface. In other words, when viewing the inclined surface 900t from above, the inclined surface 900t fails to have a rectangular shape, but has a rounded shape. Further, it results that the inclined surface 37t of the insulating layer 37, which is patterned using such a resist layer 900, fails to have the large area, but is rounded similarly to the resist layer 900. This phenomenon becomes conspicuous as miniaturization of the solid-state imaging device progresses.

The reason is as follows. If the miniaturization of the solid-state imaging device progresses, miniaturization of a pixel also progresses. It results that the number of the transparent sections (or the light shielding sections) of the grating mask 80 in one pixel decreases accordingly. Thus, the exposure accuracy in forming the inclined surfaces 900t of the resist layer 900 in one pixel decreases.

If the color light separation sections 21, 22 are formed on the inclined surfaces 37t of the insulating layer 37, each of the color light separation sections 21, 22 does not have a sufficiently large area since the foundation layer has a rounded shape. As a result, an amount of the green light transmitted through each of the color light separation sections 21, 22, and amounts of the blue light and the red light reflected by each of the color light separation sections 21, 22 decrease. Therefore, in the reference example, the optical sensitivity of the solid-state imaging device decreases.

Here, there is a method of increasing the number of the transparent sections (or the light shielding sections) of the grating mask 80 in accordance with the miniaturization of the solid-state imaging device to thereby increase the accuracy of the exposure using the grating mask 80. However, this method requires a further accurate processing technology in processing the grating mask 80 itself. Therefore, according to this method, the price of the grating mask 80 rises.

In contrast, in the first embodiment, the resist layer 90 thus developed does not have a steep rising section unlike the reference example. For example, an angle of a part (a top portion indicated by the arrow H) where the resist layer 90 has the greatest thickness is an obtuse angle)(>90°, and the inclined surfaces 90t1, 90t2 of the resist layer 90 continuously extend in the Y-direction. Then, the surface shape of the resist layer 90 is transferred to the surface of the insulating layer 37, then the multilayer film 25 (the color light separation sections 21, 22) is provided on the insulating layer 37, and subsequently, the unnecessary part of the multilayer film 25 is removed by the PEP process.

Therefore, according to the first embodiment, the insulating layer 37 having a sufficiently large inclined surface is formed as the foundation layer of each of the color light separation sections 21, 22. Therefore, it becomes difficult for an amount of the green light transmitted through each of the color light separation sections 21, 22, and amounts of the blue light and the red light reflected by each of the color light separation sections 21, 22 to decrease. In other words, according to the first embodiment, the solid-state imaging device 1 having high optical sensitivity is realized.

Further, in the first embodiment, there is no need to remake the grating mask 80 using a further accurate processing technology. Thus, an increase in price of the grating mask 80 is not incurred.

### Second Embodiment

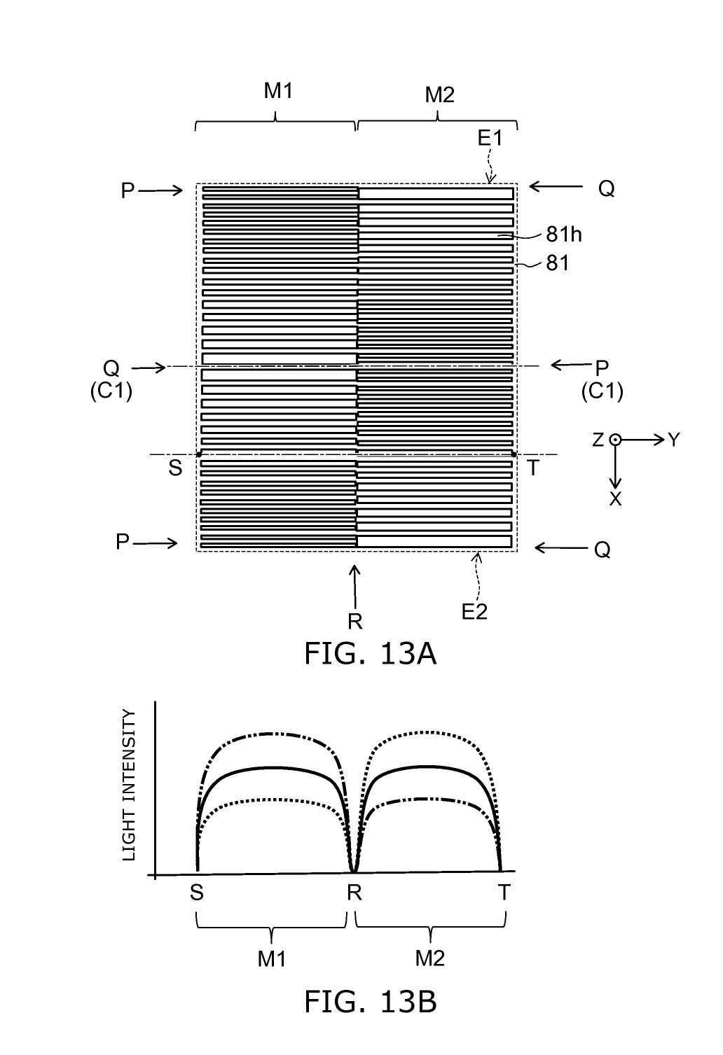

FIG. 13A is a schematic plan view of a grating mask used in the exposure process for forming the solid-state imaging device according to the second embodiment, and FIG. 13B is a graph showing an example of an intensity distribution of the light transmitted through the grating mask.

FIG. 13A shows a minimum unit of the grating mask 81.

The grating mask 81 shown in FIG. 13A includes a first mask section M1 and a second mask section M2. The first mask section M1 and the second mask section M2 are arranged side by side in a direction (the Y-direction) crossing a direction (the X-direction) from the end E1 toward the end E2. The minimum unit can expose, for example, an area corresponding to four pixels. In the grating mask 81, the minimum units are arranged in the X-direction and the Y-direction in a repeated manner. As shown in FIG. 13A, the grating mask 81 include a plurality of transparent sections 81h each having a stripe shape and arranged side by side in parallel to each other.

In the first mask section M1, the density of the pattern (the light shielding sections) for shielding the exposure light continuously decreases in an area between the end E1 and a position C1 in a direction from the end E1 toward the position C1, and the density of the light shielding sections continuously increases in an area between the position C1 and the end E2 in a direction from the position C1 toward the end E2. In the second mask section M2, the density of the light shielding sections continuously increases in the area between the end E1 and the position C1 in the direction from the end E1 toward the position C1, and the density of the light shielding sections continuously decreases in the area between the position C1 and the end E2 in the direction from the position C1 toward the end E2. Here, the position C1 is an intermediate position between the end E1 and the end E2. For example, the first mask section M1 and the second mask section M2 each have a structure including the transparent sections 81h and the line sections other than the transparent sections 81h. The widths of the plurality of transparent sections 81h increase in a direction from the position P toward the position Q. The direction from the position P toward the position Q in the first mask section M1 and the direction from the position P toward the position Q in the second mask section M2 are opposite to each other.

In the first mask section M1 and the second mask section M2, the light intensity distribution in the direction from the position P toward the position Q is the same as shown in FIG. 3B. It should be noted that a phase shifter is provided to the second mask section M2. The phase of the light transmitted through the first mask section M1 is shifted as much as 180° from the phase of the light transmitted through the second mask section M2. The phase shifter includes a material such as fluorine, tantalum, or molybdenum. It should be noted that it is also possible to provide the phase shifter to the first mask section M1 without providing the phase shifter to the second mask section M2.

FIG. 13B shows the light intensity distribution in the direction from a position S toward a position T in the grating mask 81 as an example using a solid line. The direction from the position S toward the position T is perpendicular to the direction from the position P toward the position Q. Further, a line connecting the position S and the position T to each other is positioned between the position P and the position Q. Further, in FIG. 13B, a boundary between the first mask section M1 and the second mask section M2 is defined as a position R.

The intensity distribution of the light transmitted through the grating mask 81 steeply rises in the vicinity of each of the position S, the position T, and the position R. Here, since the phase of the light transmitted through the first mask section is shifted as much as 180° from the phase of the light transmitted through the second mask section, the intensity of the light at the position R becomes roughly zero.

Further, in the case in which the line connecting the position S and the position T to each other is shifted upward in the drawing within a range between the position S and the position T, the light intensity distribution becomes as indicated by the dashed-two dotted line, and in the case in which the line connecting the position S and the position T to each other is shifted downward in the drawing within the range between the position S and the position T, the light intensity distribution becomes as indicated by the dotted line. In the cases of the dashed-two dotted line and the dotted line, the phase of the light transmitted through the first mask section is also shifted as much as 180° from the phase of the light transmitted through the second mask section. Therefore, the light intensity at the position R becomes roughly zero.

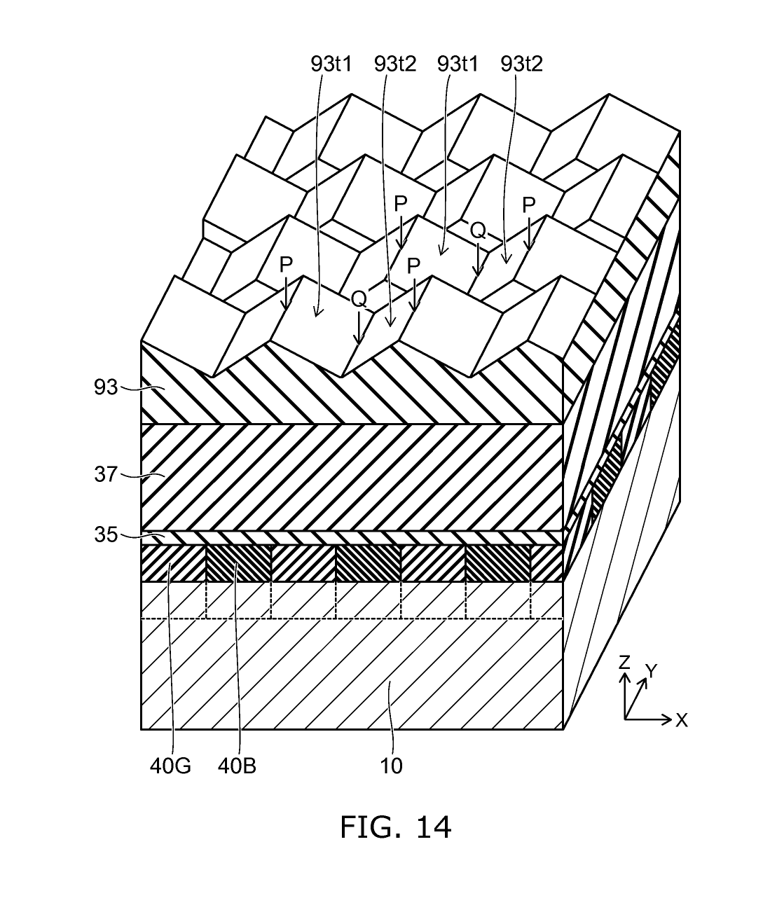

FIG. 14 is a schematic perspective view showing the state after the resist layer is irradiated with the exposure light transmitted through the grating mask and then the resist layer is developed.

On the substrate 10, there is provided the insulating layer 37 via the color filters 40G, 40B, and 40R, and the insulating film 35. On the insulating layer 37, there is provided a resist layer 93. The resist layer 93 is in the state after the resist is applied to the surface of the insulating layer 37, then irradiated with the exposure light through the grating mask 81, and then developed.

The resist layer 93 has inclined surfaces 93t1 positioned on the light receiving regions 10G1 or the light receiving regions 10G2, and inclined surfaces 93t2 positioned on the light receiving regions 10B or the light receiving regions 10R. The position where the inclined surface 93t1 and the inclined surface 93t2 are connected to each other has the smallest thickness or the greatest thickness of the thickness of the resist layer 93. An angle between the inclined surface 93t1 and the inclined surface 93t2 is the obtuse angle.

In the exposure process, in the case of disposing the grating mask 81 on the light receiving regions 10G1, the light receiving regions 10G2, the light receiving regions 10B, and the light receiving regions 10R, the grating mask 81 include the phase shifter on the light receiving regions 10G1 and the light receiving regions 10B, or on the light receiving regions 10G2 and the light receiving regions 10R. The position Q of the grating mask 81 is positioned on the position where the resist layer 93 has the smallest thickness, and the position P of the grating mask 81 is positioned on the position where the resist layer 93 has the greatest thickness. Further, when irradiating the resist layer 93 with the exposure light, the grating mask 81 include the phase shifter on the boundary between the set of the light receiving region 10G1 and the third light receiving region 10B, and the set of the light receiving region 10G2 and the light receiving region 10R.

In the Y-direction, the thickest position (the thickest position indicated by the arrow P) of the resist layer 93 provided on the light receiving region 10G2 and the light receiving region 10R is lateral to the thinnest position (the thinnest position indicated by the arrow Q) of the resist layer 93 provided on the light receiving region 10G1 and the light receiving region 10B. In the second embodiment, the resist layer 93 having such a surface shape is formed on the insulating layer 37. As described above, the inclined surfaces 93t1 are formed on the light receiving regions 10G1 and the light receiving regions 10G2, and the inclined surfaces 93t2 are formed on the light receiving regions 10B and the light receiving regions 10R so that the position where the inclined surface 93t1 and the inclined surface 93t2 are connected to each other has the smallest or the greatest thickness of the thickness of the resist layer 93, and the position having the greatest thickness of the resist layer 93 provided on the light receiving regions 10G2 and the light receiving region 10R is lateral to the position having the smallest thickness of the resist layer 93 provided on the light receiving regions 10G1 and the light receiving regions 10B.

In other words, the resist layer 93 has the thinnest position Q and the thickest position P, the inclined surface 93t1 is in contact with the inclined surface 93t2 at the thinnest position Q and the thickest position P, and the thickest position P is adjacent to the thinnest position Q.

The resist layer 93 has the inclined surfaces 93t1 positioned on the light receiving regions 10G1 or the light receiving regions 10G2, and the inclined surfaces 93t2 positioned on the light receiving regions 10B or the light receiving regions 10R.

The thickest position (the position indicated by the arrow P) of the resist layer 93 rises steeply from the thinnest position (the position indicated by the arrow Q) of the resist layer 93. This structure corresponds to the fact that the light intensity distribution of the exposure light transmitted through the grating mask 81 steeply rises at this position.

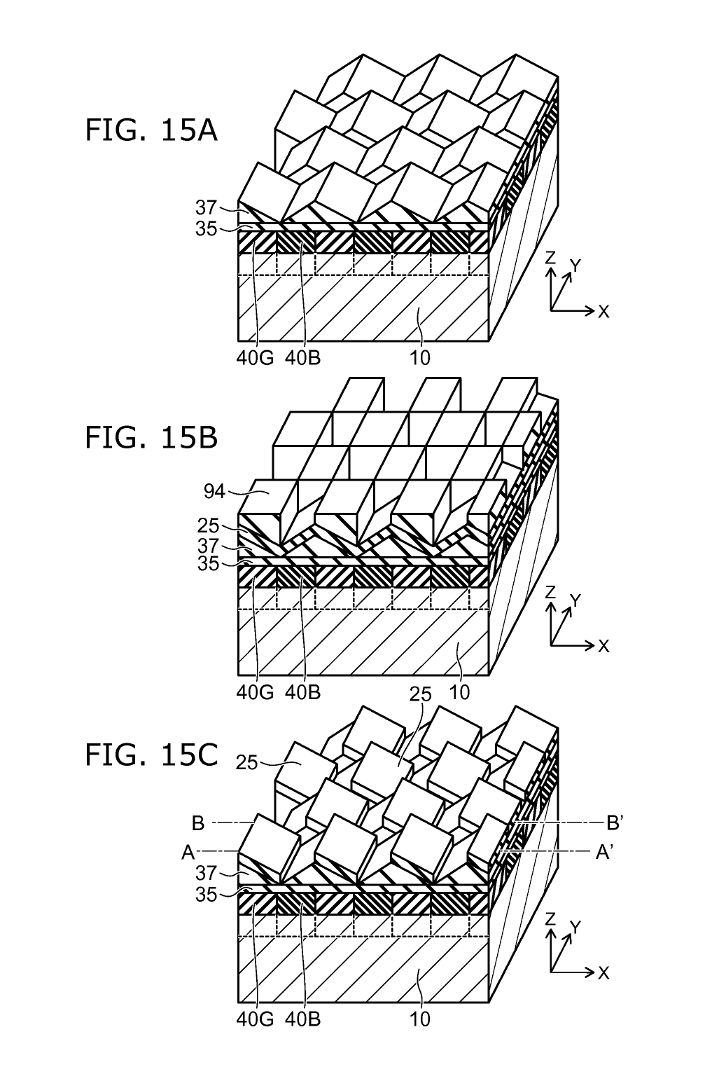

Then, the surface of the resist layer 93 is etched back using, for example, RIE to expose the surface of the insulating layer 37 from the resist layer 93. Subsequently, the RIE is continued to remove the resist layer 93 by the etchback process. Further, the surface of the insulating layer 37 thus exposed is etched back using the RIE to thereby transfer the surface shape of the resist layer 93 described above having the inclined surfaces 93t1, 93t2 to the surface of the insulating layer 37. FIG. 15A shows this state.

FIGS. 15A through 15C are schematic cross-sectional views showing a method for manufacturing the solid-state imaging device according to the second embodiment.

For example, as shown in FIG. 15A, the surface shape of the resist layer 93 is transferred to the insulating layer 37.

Then, as shown in FIG. 15B, a multilayer film 25 is formed on the insulating layer 37 to which the surface shape is transferred. Subsequently, a mask layer 94 is selectively formed on the multilayer film 25 provided on the upper side of the light receiving regions 10G1, 10G2.

Then, as shown in FIG. 15C, unnecessary portions of the multilayer film 25 are removed by a PEP process. For example, the multilayer film 25 on the light receiving regions 10B and the light receiving regions 10R is selectively removed using an RIE process. Subsequently, the mask layer 91 is removed.

Due to the RIE process, the multilayer film 25 is divided into a plurality of regions. The multilayer film 25 provided on the light receiving regions 10G1 turns to the color light separation sections 21, and the multilayer film 25 provided on the light receiving regions 10G2 turns to the color light separation sections 22.

Hereinafter, the subsequent manufacturing process will be described, wherein the multilayer film 25 thus separated is referred to as the color light separation sections 21 or the color light separation sections 22.

Further, the subsequent manufacturing process will be described using cross-sectional views instead of the perspective views. For example, the description will be presented showing cross-sectional views parallel to the X-Z plane including the A-A′ line shown in FIG. 15C and cross-sectional views parallel to the X-Z plane including the B-B′ line at the same time as an example.

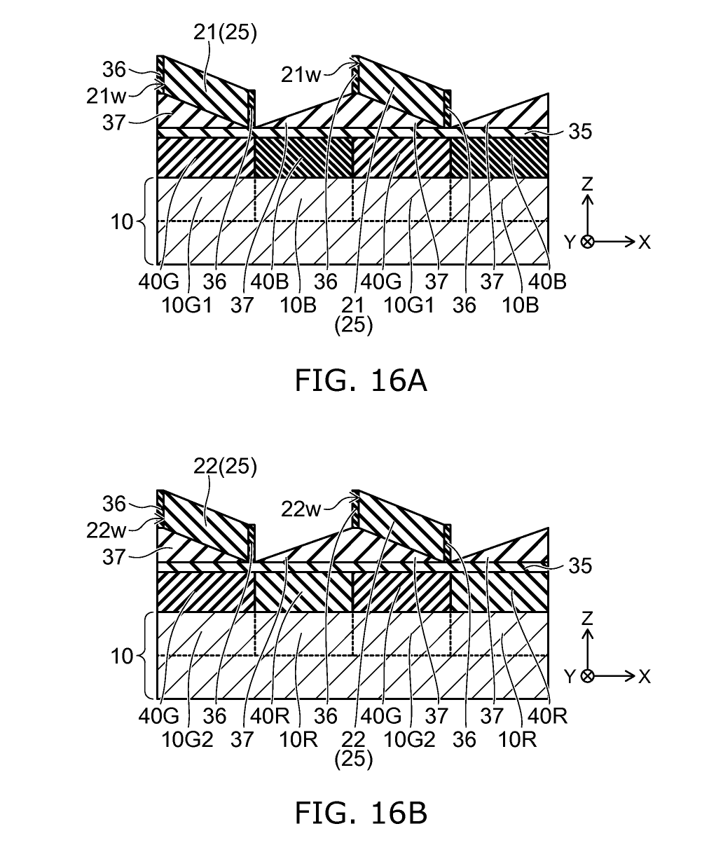

FIGS. 16A through 18B are schematic cross-sectional views showing the method for manufacturing the solid-state imaging device according to the second embodiment.

Further, among FIG. 16A through FIG. 18B, FIGS. 16A, 17A, and 18A each correspond to a cross-sectional surface in the X-Z plane including the A-A′ line shown in FIG. 15C, and FIGS. 16B, 17B, and 18B each correspond to a cross-sectional surface in the X-Z plane including the B-B′ line.

As shown in FIG. 16A and FIG. 16B, the insulating film 36 is formed on the side walls 21w of each of the color light separation sections 21, and the insulating film 36 is formed on the side walls 22w of each of the color light separation sections 22.

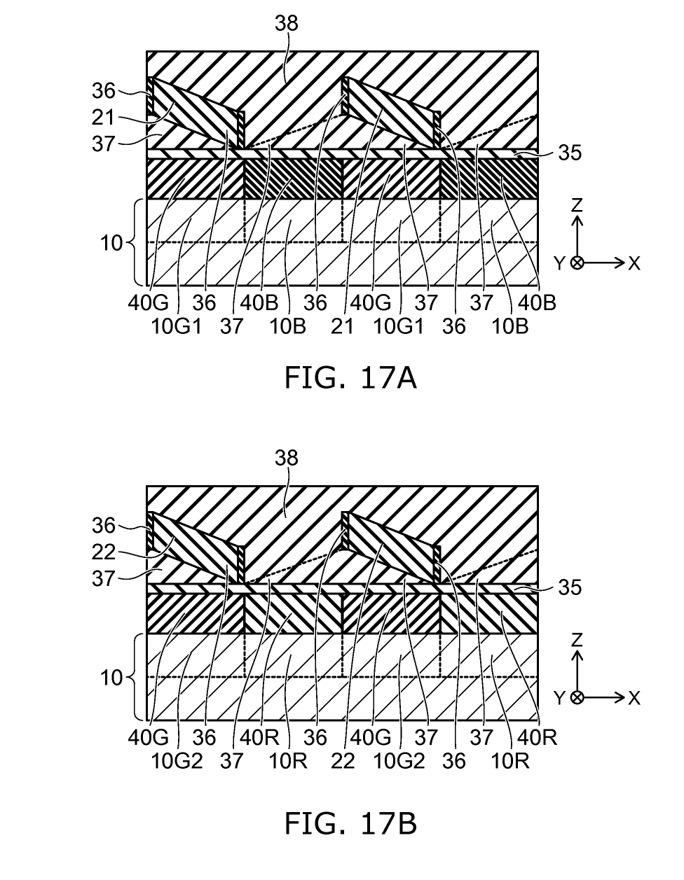

Then, as shown in FIG. 17A and FIG. 17B, the insulating layer 38 is formed on the insulating layer 37 and the color light separation sections 21, 22.

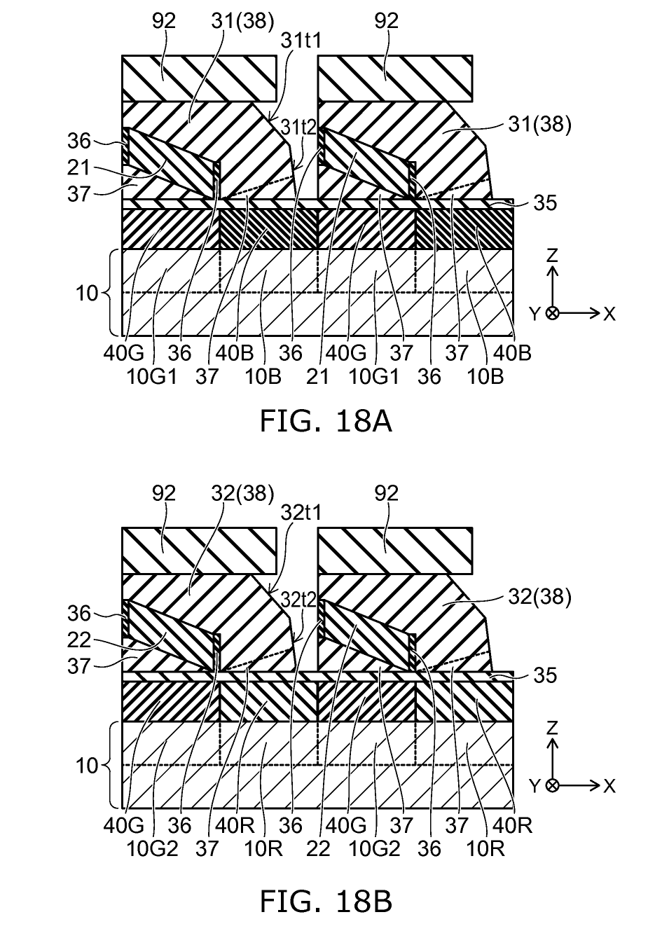

Subsequently, as shown in FIG. 18A and FIG. 18B, the mask layer 92 is selectively formed on the insulating layer 38. Subsequently, the insulating layer 38 is separated using anisotropic etching such as RIE and isotropic etching in combination with each other. For example, the insulating layer 38 is selectively formed on the light receiving region 10G1 and the light receiving region 10B, and on the light receiving region 10G2 and the light receiving region 10R. Hereinafter, the subsequent manufacturing process will be described, wherein the insulating layer 38 thus separated is referred to as the waveguide sections 31 or the waveguide sections 32.

The waveguide sections 31 are each formed on the light receiving region 10G1 and the light receiving region 10B, and the waveguide sections 32 are each formed on the light receiving region 10G2 and the light receiving region 10R. Here, the insulating layer 37 under the insulating layer 38 forms a part of the waveguide section 31 or the waveguide section 32. In the case in which the material of the insulating layer 37 is the same as the material of the insulating layer 38, the waveguide section 31 or the waveguide section 32 becomes a layer having homogenous or roughly homogenous refractive index.

Further, each of the inclined surfaces 31t1, 31t2 provided to the waveguide section 31 is arbitrarily adjusted in angle by adjusting etching conditions. Further, each of the inclined surfaces 32t1, 32t2 provided to the waveguide section 32 is arbitrarily adjusted in angle by adjusting the etching conditions. Subsequently, the mask layer 92 is removed.

Subsequently, the metal layer 50 is formed on the waveguide sections 31 each provided on the light receiving region 10G1 and the light receiving region 10B, and on the waveguide sections 31 each provided on the light receiving region 10G2 and the light receiving region 10R. Further, the metal layer 50 is selectively etched to form the waveguides 71W, 72W. Subsequently, the lenses 71L, 72L are formed. The solid-state imaging device formed using such a manufacturing process as described above is referred to as the solid-state imaging device 2.

In the second embodiment, the insulating layer 37 having a sufficiently large inclined surface is also formed as the foundation layer of each of the color light separation sections 21, 22. Therefore, it becomes difficult for an amount of the green light transmitted through each of the color light separation sections 21, 22, and amounts of the blue light and the red light reflected by each of the color light separation sections 21, 22 to decrease. In other words, according to the second embodiment, the solid-state imaging device 2 having high optical sensitivity is realized.

In the second embodiment, the inclined surfaces 21t of the color light separation sections 21 and the inclined surfaces 22t of the color light separation sections 22 face the same direction. Thus, in the solid-state imaging device 2, a direction in which the blue light or the red light is guided from the color light separation section 21 to the light receiving region 10B, and a direction in which the blue light or the red light is guided from the color light separation section 22 to the light receiving region 10R are the same as each other.

For example, in the solid-state imaging device of the related art, in the case in which the inclined surfaces 21t of the color light separation sections 21 and the inclined surfaces 22t of the color light separation sections 22 face the same direction, a change in layout of the pixels of the solid-state imaging device of the related art is not required in the second embodiment. Thus, in the second embodiment, a signal processing method used in the solid-state imaging device of the related art can directly be applied.

Further, if the light enters the light receiving regions from the camera lens, an amount of the light, which enters perpendicularly to the light receiving regions, is relatively large in the light receiving regions disposed in the central portion, and an amount of the light, which enters obliquely to the light receiving regions, is relatively large in the light receiving regions disposed in the peripheral portion. Therefore, in the solid-state imaging device, there is a possibility that the color shading occurs between the central portion and the peripheral portion of the pixel array.

In order to suppress the color shading, the sensitivity to the light received in the light receiving regions disposed in the central portion or the sensitivity to the light received in the light receiving regions disposed in the peripheral portion is corrected in some cases. According to the second embodiment, the inclined surfaces 21t of the color light separation sections 21 and the inclined surfaces 22t of the color light separation sections 22 face the same direction. Thus, in the second embodiment, the correction values used in the solid-state imaging device of the related art can be applied, but it is not required to newly derive the correction values.

In the embodiments described above, “on” in “A is provided on B” means the case where the A contacts the B and the A is provided on the B and the case where the A does not contact the B and the A is provided above the B. “A is provided on B” may include the case where the A and the B are reversed and A is positioned below the B and the case where the A is arranged along with the B.

Although the embodiments are described above with reference to the specific examples, the embodiments are not limited to these specific examples. That is, design modification appropriately made by a person skilled in the art in regard to the embodiments is within the scope of the embodiments to the extent that the features of the embodiments are included. Components and the disposition, the material, the condition, the shape, and the size or the like included in the specific examples are not limited to illustrations and can be changed appropriately.

The components included in the embodiments described above can be combined to the extent of technical feasibility and the combinations are included in the scope of the embodiments to the extent that the feature of the embodiments is included. Various other variations and modifications can be conceived by those skilled in the art within the spirit of the invention, and it is understood that such variations and modifications are also encompassed within the scope of the invention.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the invention.

What is claimed is:

1. A solid-state imaging device comprising:
a substrate including a first region receiving a first color light, a second region receiving the first color light, a third region receiving a second color light, and a fourth region receiving region receiving a third color light;
a first color light separation section provided on the first region, the first color light separation section having a first inclined surface, an angle of the first inclined surface to a horizontal direction on the substrate being a first angle;
a first layer provided on the first color light separation section;
a first light collecting section provided above the first region;
a second color light separation section provided on the second region, the second color light separation section having a second inclined surface, an angle of the second inclined surface to the horizontal direction on the substrate being a second angle;
a second layer provided on the second color light separation section; and
a second light collecting section provided above the second region.

2. The device according to claim 1, wherein
the first color light is transmitted in the first color light separation section and the second color light separation section,
a light transmittance to the first color light is greater than a light transmittance to the second color light and the third color light in the first color light separation section and the second color light separation section.

3. The device according to claim 1, wherein
the first inclined surface has an angle to a direction from the substrate toward the first light collecting section.

4. The device according to claim 1, wherein
the first layer is provided on the third region.

5. The device according to claim 1, wherein
the second layer is provided on the fourth region.

6. The device according to claim 1, wherein
the first layer has a third inclined surface facing the first inclined surface.

7. The device according to claim 1, wherein
the second layer has a fourth inclined surface facing the second inclined surface.

8. The device according to claim 1, wherein
the first layer and the second layer have a transparent material.

9. The device according to claim 1, further comprising:
a metal layer provided on the first layer, the second layer, the third region, and the fourth region.

10. The device according to claim 1, wherein
the first region is positioned beside the third region in a first direction, the fourth region is positioned beside the first region in a second direction, and the fourth region is positioned beside the second region in the first direction.

11. The device according to claim 10, wherein
the first region is positioned beside the second region in a first diagonal direction, and the third region is positioned beside the fourth region in a second diagonal direction.

12. A method for manufacturing a solid-state imaging device, comprising:
forming a first insulating layer on a substrate including a first region receiving a first color light, a second region receiving the first color light, a third region receiving a second color light, and a fourth region receiving a third color light;
forming a resist layer on the first insulating layer, the resist layer having a first inclined surface positioned on the first region and the fourth region and a second inclined surface positioned on the second region and the third region, an angle between the first inclined surface and the second inclined surface being an obtuse angle, and the resist layer having a first position and a second position, a thickness of the resist layer at the first position being minimal thickness, the thickness of the resist layer at the second position being maximal thickness, the first inclined surface being in contact with the second inclined surface at the first position and the second position;
transferring a surface shape including the first inclined surface and the second inclined surface to the first insulating layer by etching the resist layer and the first insulating layer;
forming a multilayer film on the first insulating layer; and
removing the multilayer film positioned on the third region and the fourth region.

13. The method according to claim 12, wherein
the forming the resist layer on the first insulating layer includes irradiating the resist layer with exposure light via a mask, and
an intensity of the exposure light transmitted through the mask increases from the second position of the resist layer toward the first position of the resist layer.

14. The method according to claim 12, wherein
a positive resist layer is used as the resist layer.

15. The method according to claim 13, wherein
the mask includes a plurality of units arranged in a first direction and a second direction crossing the first direction, and
each of the plurality of units has patterns shielding the exposure light,
a first end faces a second end in one of the units, and a distance between an adjacent patterns decreases from the first end toward the second end gradually.

16. The method according to claim 12, further comprising:
forming a second insulating layer on the first insulating layer and the multilayer film.

17. The method according to claim 16, wherein
the second insulating layer is selectively formed on the first region and the third region, and on the second region and the fourth region.

18. The method according to claim 17, further comprising:
forming a metal layer on a surface of the second insulating layer provided on the first region and the third region, and on a surface of the second insulating layer provided on the second region and the fourth region.

19. The method according to claim 16, wherein
a material of the first insulating layer includes a same material as the second insulating layer.

20. A method for manufacturing a solid-state imaging device, comprising:
forming a first insulating layer on a substrate including a first region receiving a first color light, a second region receiving the first color light, a third region receiving a second color light, and a fourth region receiving a third color light;
forming a resist layer on the first insulating layer, the resist layer having a first inclined surface positioned on the first region and the second region and a second inclined surface positioned on the third region and the fourth region, an angle between the first inclined surface and the second inclined surface being an obtuse angle, the resist layer having a first position and a second position, a thickness of the resist layer at the first position being minimal thickness, the thickness of the resist layer at the second position being maximal thickness, the first inclined surface being in contact with the second inclined surface at the first position and the second position, and the second position is adjacent to the first position;
transferring a surface shape including the first inclined surface and the second inclined surface to the first insulating layer by etching the resist layer and the first insulating layer;
forming a multilayer film on the first insulating layer; and
removing the multilayer film positioned on the third region and the fourth region.
